(19) United States
(12) Patent Application Publication
(10) Pub. No.: US 2013/0313514 A1
(43) Pub. Date: Nov. 28, 2013

(54) SEMICONDUCTOR LIGHT EMITTING DEVICE

(71) Applicant: SAMSUNG ELECTRONICS CO., LTD., Suwon-si (KR)

(72) Inventors: Kyung Wook HWANG, Hwaseong (KR); Geon Wook YOO, Seongnam (KR); Nam Goo CHA, Ansan (KR); Jae Hyeok HEO, Seogwipo-si (KR); Han Kyu SEONG, Seoul (KR); Hun Jae CHUNG, Yongin (KR)

(73) Assignee: SAMSUNG ELECTRONICS CO., LTD., Suwon-si (KR)

(21) Appl. No.: 13/842,812

(22) Filed: Mar. 15, 2013

(30) Foreign Application Priority Data
May 23, 2012 (KR) 10-2012-0054692
Jan. 24, 2013 (KR) 10-2013-0008121

(51) Int. Cl. H01L 33/16

(52) U.S. Cl. CPC H01L 33/16; Y10S 977/762; B82Y 99/00
USPC 257/13; 977/762

(57) ABSTRACT

There is provided a semiconductor light emitting device including: a substrate and a nanostructures spaced apart from one another on the substrate. The nanostructures includes a first conductivity-type semiconductor layer core, an active layer, and a second conductivity-type semiconductor layer. A filler fills spaces between the nanostructures and is formed to be lower than the plurality of nanostructures. An electrode is formed to cover upper portions of the nanostructures and portions of lateral surfaces of the nanostructures and electrically connected to the second conductivity-type semiconductor layer.

### CROSS-REFERENCE TO RELATED APPLICATIONS

This application claims the priority to Korean Patent Application No. 10-2012-0054692 filed on May 23, 2012, and No. 10-2013-0008121 filed on Jan. 24, 2013, in the Korean Intellectual Property Office, the disclosures of which are incorporated herein by reference.

### TECHNICAL FIELD OF THE INVENTION

The present application relates to a semiconductor light emitting device.

### BACKGROUND

A light emitting diode (LED), known as a next generation light source, has many positive attributes such as a relatively long lifespan, low power consumption, a rapid response rate, environmentally friendly characteristics, and the like, as compared with a light source according to the related art. The LED has been used as an important light source in various products such as illumination devices and back light units for display devices. In particular, Group III nitride-based LEDs including GaN, AlGaN, InGaN, InAlGaN, and the like have been used in semiconductor light emitting devices outputting blue or ultraviolet light.

Recently, as LEDs have come into widespread use, the range of use thereof has been enlarged within the field of a high current, high output light sources. As described above, as LEDs are required in the field of high current and high output light sources. Research into improving light emitting characteristics in the technological field of the present technology has continued and there have been efforts to improve a growth conditions for a multiple quantum well (MQW) structure or crystalline properties of a semiconductor layer. In particular, in order to increase light efficiency through an improvement in crystalline properties and an increase in a light emission region, a nanorod-based light emitting device having a nitride semiconductor nanorod structure and a manufacturing technology thereof have been proposed. Such a nitride semiconductor nanorod-based light emitting device may implement light emissions by using an indium gallium nitride/gallium nitride (InGaN/GaN) multiple quantum well structure in an active layer.

There still remains room for improvement in light emitting devices in terms of enhanced light extraction efficiency.

### SUMMARY

A novel semiconductor light emitting device including a nanostructure having enhanced light extraction efficiency is required.

According to an aspect of the present application, there is provided a semiconductor light emitting device. The device includes a substrate and a plurality of nanostructures spaced apart from one another on the substrate. The nanostructures include a first conductivity-type semiconductor layer core, an active layer, and a second conductivity-type semiconductor layer. A filler fills spaces between the plurality of nanostructures and is formed to be lower than the nanostructures. An electrode is formed to cover upper portions of the nanostructures and portions of lateral surfaces of the nanostructures and electrically connected to the second conductivity-type semiconductor layer.

A height of the filler may be equivalent to ⅗ or greater of a height of the plurality of nanostructures.

The electrode may be formed to cover a portion of the lateral surface of the plurality of nanostructures, equivalent to ⅖ or less of the length of the lateral surface of the plurality of nanostructures from an upper portion of the plurality of nanostructures.

The filler may be made of a light-transmissive material.

The semiconductor light emitting device may further include a laterally sloped layer formed on a lateral surface of at least one of the plurality of nanostructures, and sloped at a predetermined angle with respect to an upper surface of the substrate.

The predetermined angle may be greater than 45° and less than 90°.

The plurality of nanostructures may have a nanorod shape.

The plurality of nanostructures may include a plurality of semi-polar surfaces.

The electrode may be made of a light-reflective material.

According to another aspect of the present application, there is provided a semiconductor light emitting device. The device includes a substrate and a plurality of nanostructures having nanorod shapes, spaced apart from one another on the substrate and the nanostructures include a first conductivity-type semiconductor layer core, an active layer, and a second conductivity-type semiconductor layer. A laterally sloped layer is formed on at least one of the plurality of nanostructures and is sloped at a predetermined angle with respect to an upper surface of the substrate.

The predetermined angle may be greater than 45° and less than 90°.

The plurality of nanostructures may include a first conductivity-type semiconductor layer core, an active layer surrounding the core, and a second conductivity-type semiconductor layer surrounding the active layer.

A light emitting unit including the plurality of nanostructures and the laterally sloped layer may have a trapezoidal shape when viewed from the side thereof.

The laterally sloped layer may be made of the same material as that of the second conductivity-type semiconductor layer.

The laterally sloped layer may be made of a material having a refractive index different from that of the second conductivity-type semiconductor layer.

Additional advantages and novel features will be set forth in part in the description which follows, and in part will become apparent to those skilled in the art upon examination of the following and the accompanying drawings or may be learned by production or operation of the examples. The advantages of the present teachings may be realized and attained by practice or use of various aspects of the methodologies, instrumentalities and combinations set forth in the detailed examples discussed below.

### BRIEF DESCRIPTION OF THE DRAWINGS

The above and other aspects, features and other advantages of the present application will be more clearly understood from the following detailed description taken in conjunction with the accompanying drawings, in which:

FIG. 1 is a cross-sectional view of a semiconductor light emitting device including a nanostructure according to a first example;

FIG. 2 is a cross-sectional view of a semiconductor light emitting device including nanostructures according to a second example;

FIG. 3 is a cross-sectional view of a semiconductor light emitting device including nanostructures according to a third embodiment of the present invention;

FIG. 4 is a cross-sectional view illustrating an insulating layer including a plurality of openings having different diameters;

FIG. 5 is a plan view illustrating an insulating layer including a plurality of openings having different diameters;

FIG. 6 is a graph showing light extraction efficiency over ratios between fillers provided between nanostructures of a semiconductor light emitting devices and heights of electrodes formed on upper portions of the fillers according to the first and third embodiments of the present invention;

FIG. 7 is a cross-sectional view of a semiconductor light emitting device including nanostructures according to a fourth example;

FIG. 8 is a cross-sectional view of a semiconductor light emitting device including nanostructures according to a fifth example;

FIG. 9 is a cross-sectional view illustrating the intensity of light according to respective directions of light L emitted laterally from a point A of a semiconductor light emitting device having a light emitting unit having a lateral surface perpendicular to a substrate;

FIG. 10 is a graph illustrating the intensity of light according to a light emission distance of the light L emitted from the point A of the semiconductor light emitting device of FIG. 9 in the horizontal direction;

FIG. 11 is a cross-sectional view illustrating the intensity of light according to respective directions of light L2 emitted from a point B of a semiconductor light emitting device having a light emitting unit having a lateral surface sloped at a predetermined angle with respect to an upper surface of a substrate;

FIG. 12 is a graph illustrating the intensity of light according to a light emission distance of the light L2 emitted from the point B of the semiconductor light emitting device of FIG. 11 in the horizontal direction;

FIG. 13 is a graph illustrating the strength of light emitted from a point of a semiconductor light emitting device in horizontal directions according to emission distances of light for each inclination of respective light emitting units;

FIG. 14 is a cross-sectional view illustrating a semiconductor light emitting device according to a sixth example;

FIG. 15 is a cross-sectional view illustrating a semiconductor light emitting device according to a seventh example;

FIG. 16 is a view illustrating an example of the application of the semiconductor light emitting device of FIG. 15 to a package;

FIG. 17 is a view illustrating an example of the application of a semiconductor light emitting device to a package;

FIGS. 18 and 19 are views illustrating examples of applications of a semiconductor light emitting device to a backlight unit;

FIG. 20 is a view illustrating an example of an application of a semiconductor light emitting device to an illuminating device; and

FIG. 21 is a view illustrating an example of an application of a semiconductor light emitting device to a head lamp.

### DETAILED DESCRIPTION

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, and/or circuitry have been described at a relatively high-level, without detail, in order to avoid unnecessarily obscuring aspects of the present teachings.

In the drawings, the shapes and dimensions of elements may be exaggerated for clarity, and the same reference numerals will be used throughout to designate the same or like elements.

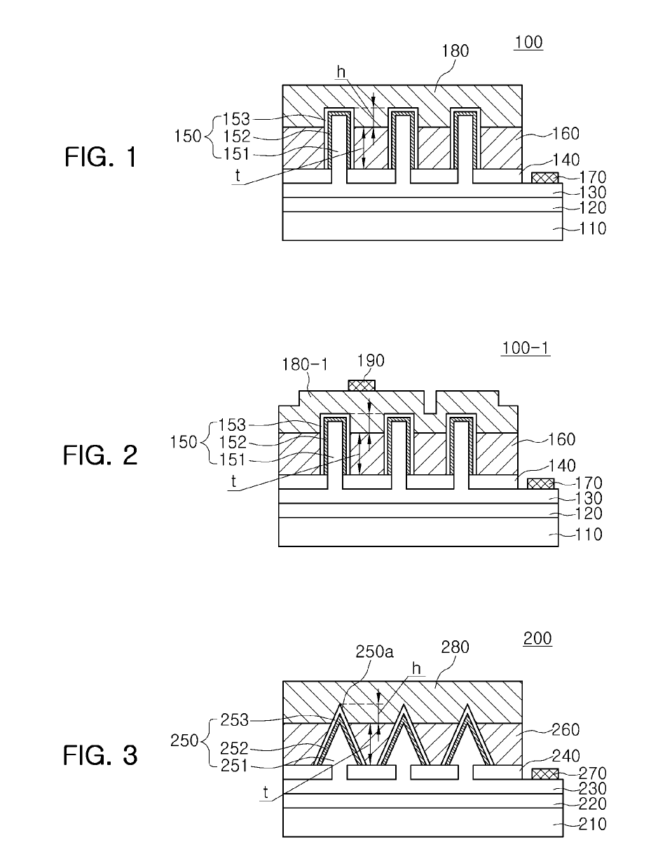

FIG. 1 is a cross-sectional view of a semiconductor light emitting device having a nanostructure according to a first example, illustrating a flip-chip type semiconductor light emitting device. However, in FIG. 1, a substrate is illustrated as being positioned on a lower side.

Referring to FIG. 1, the semiconductor light emitting device 100 according to a first example includes a substrate 110, a buffer layer 120, a first conductivity-type semiconductor base layer 130 formed on the substrate 110 or the buffer layer 120, an insulating layer 140, a nanostructure 150 including a first conductivity-type semiconductor layer core 151 extending from the first conductivity-type semiconductor base layer 130, an active layer 152, and a second conductivity-type semiconductor layer 153, a filler 160 filling spaces between the nanostructures 150, a first electrode 170 formed on an exposed upper surface of the first conductivity-type semiconductor base layer 130, and a second electrode 180 formed on upper portions of the nanostructures 150 and an upper portion of the filler 160. However, terms such as ‘upper portion’, ‘upper surface’, ‘lower portion’, lower surface’, ‘lateral surface’, and the like, are based on drawings, and may differ according to directions in which devices are actually disposed.

The substrate 110, provided as a semiconductor growth substrate, may be formed of one material selected from a group consisting of sapphire, SiC, MgAl₂O₄, MgO, LiAlO₂, LiGaO₂ and GaN. In case of a sapphire substrate commonly used as a nitride semiconductor growth substrate, sapphire may be a crystal having Hexa-Rhombo R3c symmetry, may have respective lattice constants of 13.001 Å and 4.758 Å in c-axis and a-axis directions, and may have a C (0001) plane, an A (1120) plane, an R (1102) plane and the like. In this case, since the C plane comparatively facilitates the growth of a nitride thin film and is stable at relatively high temperatures, the C plane may be mainly used as a growth substrate for a nitride semiconductor.

Meanwhile, a silicon (Si) substrate may also be appropriate to be used as the substrate 110. The use of a silicon substrate, which should have a large diameter and be relatively low in price, may facilitate mass-production. In the case in which a silicon substrate is used, a nucleation layer made of AlxGa1-xN may be formed on the substrate 110 and a nitride semiconductor having a desired structure may be grown thereon.

An uneven or sloped surface may be formed on a plane (a surface or both surfaces) or a lateral surface of the substrate 110 to enhance light extraction efficiency. A size of a pattern may be selected from a range of 5 nm to 500 μm, and may be smaller or larger in consideration of a size of a chip without causing a problem. Any structure may be employed as long as it can enhance light extraction efficiency. The pattern may have various shapes such as a columnar shape, a peaked shape, and a hemispherical shape.

The buffer layer 120 may be formed on the substrate 110. The buffer layer 120 may be formed to alleviate lattice mismatching between the substrate 110 and the first conductivity-type semiconductor base layer 130. When a GaN thin film is grown on a heterogeneous substrate, a great deal of defects may be generated due to a lattice constant mismatch between the substrate and the thin film, and cracks may be generated due to warpage resulting from a difference between coefficients of thermal expansion. In order to control defects and warpage, the buffer layer 120 may be formed on the substrate 110 and a nitride semiconductor having a desired structure may be grown thereon. The buffer layer 120 may be made of AlxInyGa1-x-yN (0≦x≦1, 0≦y≦1), and in particular, it is largely made of GaN, AlN, or AlGaN. Also, materials such as ZrB₂, HfB₂, ZrN, HfN, and TiN may also be used. Further still, a plurality of layers may be combined to be used as the buffer layer 120 or compositions may be used by gradually changing them.

The buffer layer 120 may be formed at a relatively low temperature without doping. The buffer layer 120 may be omitted.

The first conductivity-type semiconductor base layer 130 may be formed on the substrate 110 or the buffer layer 120. The first conductivity-type semiconductor base layer 130 may be formed of a group III-V compound. The first conductivity-type semiconductor base layer 130 may be formed of gallium nitride (GaN). The first conductivity-type semiconductor base layer 130 may be formed by n-doping. Here, n-doping refers to a doping using a group V element. The first conductivity-type semiconductor base layer 130 may be a n-GaN layer.

The insulating layer 140 may be formed on the first conductivity-type semiconductor base layer 130. The insulating layer 140 may be made of a silicon oxide or a silicon nitride. For example, the insulating layer 140 may be made of SiOx, SixNy, TiO2, Al₂O₃, or the like. The insulating layer 140 may include a plurality of openings to expose portions of the first conductivity-type semiconductor base layer 130. The openings may be used for designating diameters, lengths, and positions of nanostructures to be grown through a collective process. The openings may have various shapes such as a quadrangular shape, a hexagonal shape, or the like, in addition to a circular shape. The plurality of openings may have the same diameter. Also, the plurality of openings may have different diameters.

The nanostructure 120 may include a first conductivity-type semiconductor layer core 151 extending from the first conductivity-type semiconductor base layer 130 and having a protruded shape, and an active layer 152 and a second conductivity-type semiconductor layer 153 sequentially disposed on the surface of the first conductivity-type semiconductor layer core 151. The nanostructure 150 may be disposed on the nano-scale.

The first conductivity-type semiconductor layer core 151 and the second conductivity-type semiconductor layer 153 may be configured as semiconductors doped with n-type and p-type impurities. However, the present application is not limited thereto and, conversely, the first conductivity-type semiconductor layer core 151 and the second conductivity-type semiconductor layer 153 may be p-type and n-type semiconductor layers, respectively.

The first conductivity-type semiconductor layer core 151 may extend from the exposed first conductivity-type semiconductor base layer 130. The first conductivity-type semiconductor layer core 151 may be formed by growing the first conductivity-type semiconductor base layer 130. A cross-section of the first conductivity-type semiconductor layer core 151 may have a circular or polygonal shape.

The active layer 152 may be formed to cover the first conductivity-type semiconductor layer core 151. The active layer 152 may surround an upper portion and lateral surfaces of the first conductivity-type semiconductor layer core 151. The active layer 152 may be formed of a single material such as InGan, or the like, or may also have an MQW structure in which a quantum barrier layer and a quantum well layer are alternately disposed, which are formed of, for example, Gan and InGan, respectively. In the active layer 152, light energy may be generated through the combination of electrons and holes.

The second conductivity-type semiconductor layer 153 may be formed to surround the active layer 152. The second conductivity-type semiconductor layer 153 may cover an upper surface and lateral surfaces of the active layer 152. The second conductivity-type semiconductor layer 153 may be a group III-V compound layer. The second conductivity-type semiconductor layer 153 may be p-doped. Here, p-doping may refer to a doping using a group III element. In addition, the second conductivity-type semiconductor layer 153 may be doped with a magnesium (Mg) impurity. The second conductivity-type semiconductor layer 153 may be a GaN layer. The second conductivity-type semiconductor layer 153 may be a p-GaN layer. Holes may move to the active layer 152 through the second conductivity-type semiconductor layer 153.

The filler 160 may be further disposed between the nanostructures 150. Namely, the filler 160 may be disposed on the insulating layer 140 between adjacent nanostructures 150. Here, the filler 160 may serve as a support preventing collapse of the nanostructures 150 due to external pressure.

The filler 160 may be made of an insulating material or a transparent conductive material. For example, the filler 160 may be made of Spin On Glass (SOG), SiO₂, ZnO, SiN, Al₂O₃, Indium Tin Oxide (ITO), Tin Oxide (TO), Indium Zinc Oxide (IZO), Indium Tin Zinc Oxide (ITZO), or Transparent Conductive Oxide (TCO). Also, the filler 160 may be made of a light-transmissive material in terms of a functional aspect. Here, when the filler 160 is made of a transparent material, holes may be more advantageously spread to the second conductivity-type semiconductor layer 153.

Also, the filler 160 may have a predetermined refractive index. The filler 160 may be made of a material having a refractive index equal to or lower than that of the nanostructure 150. For example, the refractive index of the filler 160 may range from 1 to 2.5.

Also, the filler 160 may have a height t lower than an upper surface of the nanostructure 150. However, if the filler 160 is too low, the second electrode 180 to be formed on the nanostructure 150 afterwards may surround the nanostructure 150 excessively, leading to light emitted from the active layer 152 being absorbed by the second electrode 180 made of metal, reducing light extraction efficiency. Thus, the filler 160 may be formed to be approximately ⅗ or more of the height (h+t) of the nanostructure 150. The filler 160 formed thusly may serve to effectively emit light generated by the active layer 152 outwardly, further enhancing a light output of the light emitting device.

The first electrode 170 may be formed on an exposed upper surface of the first conductivity-type semiconductor base layer 130 and electrically connected to the first conductivity-type semiconductor layer core 151.

The second electrode 180 may be formed on an upper portion of the nanostructure 150 and an upper portion of the filler 160 and may be electrically connected to the second conductivity-type semiconductor layer 153. The second electrode 180 may be a reflective electrode. Namely, the second electrode 180 may be made of a light reflective material, e.g., a highly reflective metal, and in this case, in the light emitting device 100, the first and second electrodes 170 and 180 may be mounted toward a lead frame, or the like, of the package. Thus, a partial amount of light emitted from the active layer 152 of the nanostructure 150 may be absorbed by the second electrode 180, and another partial amount of light may be reflected by the second electrode 180 and emitted in a direction toward the substrate 110.

In the present example, a height h of the second electrode 180 between nanostructures 150 is approximately ⅖ or less of the height (h+t) of the nanostructure 150.

Namely, the second electrode 180 may be formed to cover the nanostructure 150 by approximately ⅖ or less of the lateral length of the nanostructure 150.

Thus, since the second electrode 180 is formed to only cover a portion of the lateral surface of the nanostructure 150, absorption of light emitted from active layer 152 of the nanostructure 150 by the second electrode 180 is reduced, and since the second electrode 180 is formed to surround up to a portion of the lateral surface of the nanostructure 150, efficiency of injecting a current into the second conductivity-type semiconductor layer 153 is not reduced. Namely, by the structure of the second electrode 180, light extraction efficiency can be enhanced without reducing efficiency of injecting a current into the second conductivity-type semiconductor layer 153.

FIG. 2 is a cross-sectional view illustrating a semiconductor light emitting device having nanostructures according to a second example, in which a horizontal semiconductor light emitting device in which electrodes face upwardly is illustrated.

A semiconductor light emitting device 100-1 according to the second example includes a substrate 110, a buffer layer 120, a first conductivity-type semiconductor base layer 130 formed on the substrate 110 or the buffer layer 120, an insulating layer 140, a nanostructure 150 including a first conductivity-type semiconductor layer core 151 extending from the first conductivity-type semiconductor base layer 130, an active layer 152, and a second conductivity-type semiconductor layer 153, a filler 160 filling spaces between the nanostructures 150, a first electrode 170 formed on an exposed upper surface of the first conductivity-type semiconductor base layer 130, and an ohmic-electrode layer 180-1 and a second electrode 190 formed on an upper portion of the nanostructure 150 and an upper portion of the filler 160.

The semiconductor light emitting device 100-1 according to the second example has the same configuration as the semiconductor light emitting device 100 according to the first example, except for a material used to form the filler 160, a material used to form the ohmic-electrode layer 180-1, and the presence of the second electrode 190 formed on an upper surface of the ohmic-electrode layer 180-1.

In the second example, since light emitted from the active layer 152 of the semiconductor light emitting device is emitted upwardly from the semiconductor light emitting device, so the filler 160 may have insulating properties in a functional aspect and may be made of a transparent material. For example, the filler 160 may be made of SiOx, SixNy, or the like. Also, the filler 160 may have a predetermined refractive index and may be made of a material having the same refractive index as that of the nanostructure 150 or a material having a refractive index lower than that of the nanostructure 150. For example, a refractive index of the filler 160 may range from 1 to 2.5.

The ohmic-electrode layer 180-1 may be disposed on an upper portion of the nanostructure 150 and an upper portion of the filler 160, and may be electrically connected to the second conductivity-type semiconductor layer 153. The ohmic-electrode layer 180-1 may be made of a transparent material and may be made of indium tin oxide (ITO).

Thus, light emitted from the active layer 152 of the nanostructure 150 may be emitted upwardly from the semiconductor light emitting device through the ohmic-electrode layer 180-1.

In the present example, a height h of the ohmic-electrode layer 180-1 between the nanostructures 150 is approximately ⅖ of a height (h+t) of the nanostructure 150. Namely, the ohmic-electrode layer 180-1 is formed to cover approximately ⅖ of the length of the lateral surface of the nanostructure 150.

Thus, since the ohmic-electrode layer 180-1 is formed to only cover a portion of the lateral surface of the nanostructure 150.

Thus, since the ohmic-electrode layer 180-1 is formed to only cover a portion of the lateral surface of the nanostructure 150, absorption of light emitted from active layer 152 of the nanostructure 150 by the ohmic-electrode layer 180-1 is reduced, and since the ohmic-electrode layer 180-1 is formed to surround up to a portion of the lateral surface of the nanostructure 150, efficiency of injecting a current into the second conductivity-type semiconductor layer may not be reduced. Namely, by the structure of the ohmic-electrode layer 180-1, light extraction efficiency can be enhanced without reducing efficiency of injecting a current into the second conductivity-type semiconductor layer.

FIG. 3 is a cross-sectional view of a semiconductor light emitting device including nanostructures according to a third embodiment example. The semiconductor light emitting device having a nanostructure according to the third example is a flip-chip type semiconductor light emitting device. However, in FIG. 3, the flip-chip type semiconductor light emitting device is illustrated to have a substrate thereof placed in a lower side.

As illustrated in FIG. 3, the semiconductor light emitting device has the same components as those of the semiconductor light emitting device according to the first example in FIG. 1 as described above, except for a shape of a nanostructure.

Namely, the semiconductor light emitting device 200 may include a substrate 210, a buffer layer 220, a first conductivity-type semiconductor base layer 230 formed on the substrate 210 or the buffer layer 220, an insulating layer 240, a nanostructure 250 including a first conductivity-type semiconductor layer core 251, an active layer 252, and a second conductivity-type semiconductor layer 253, a filler 260 filling spaces between the nanostructures 250, a first electrode 270 formed on an exposed upper surface of the first conductivity-type semiconductor base layer 230, and a second electrode 280 formed on upper portions of the nanostructures 250 and an upper portion of the filler 260.

In FIG. 3, the insulating layer 240 may be formed between the nanostructures 250. As illustrated in FIG. 3, the insulating layer 240 may be exposed, rather than being covered by the nano structure 250. Alternatively, the nanostructures 250 may be formed without being separated. Thus, the insulating layer 240 may be covered by the nanostructure 250 so as not to be exposed.

The nanostructure 250 may have a plurality of semi-polar surface 250a. The semi-polar surface 250a may have a sloped surface with respect to the substrate 210. Also, the nanostructure 250 may be on the nano-scale.

The size of the nanostructure 250 may correspond to the largest diameter of the base side of the nanostructure 250. The nanostructure 250 may have a polypyramid shape.

the nanostructure 250 may freely increase the content of indium (In) in the InGaN active layer and decrease crystal defects due to lattice mismatching, increasing internal quantum efficiency. Also, in a case in which the size of the nanostructure 250 is small relative to a wavelength of light, light extraction efficiency can be increased to increase external quantum efficiency. The filler 260 may be made of an insulating material or a transparent conductive material. For example, the filler 260 may be made of Spin On Glass (SOG), SiO₂, ZnO, SiN, Al₂O₃, Indium Tin Oxide (ITO), Tin Oxide (TO), Indium Zinc Oxide (IZO), Indium Tin Zinc Oxide (ITZO), Transparent Conductive Oxide (TCO), or the like. Also, the filler 260 may be made of a light-transmissive material in a functional aspect. Here, in a case in which the filler 260 is made of a transparent conductive material, holes may be advantageously spread to the second conductivity-type semiconductor layer 253. Here, the filler 260 may have a height equal to or higher than ⅗ of the height (h+t) of the nanostructure 250.

The second electrode 280 may be formed on an upper portion of the nanostructure 250 and an upper portion of the filler 260, and may be electrically connected to the second conductivity-type semiconductor layer 253. Also, the second electrode 280 may be a reflective electrode. Namely, the second electrode 280 may be made of light reflective material, e.g., a highly reflective metal, and in this case, in the light emitting device 200, the first and second electrodes 270 and 280 may be mounted toward a lead frame, or the like, of the package. Thus, a partial amount of light emitted from the active layer 252 of the nanostructure 250 may be absorbed by the second electrode 280, and another partial amount of light may be reflected by the second electrode 280 and emitted to a light extraction surface on which the substrate 210 is formed.

In the present example, a height h of the second electrode 280 between nanostructures 250 is approximately ⅖ of the height (h+t) of the nanostructure 250. Namely, the second electrode 280 may be formed to cover the nanostructure 250 by approximately ⅖ or less of the lateral length of the nanostructure 150.

Thus, the second electrode 280 is formed to only cover a portion of the lateral surface of the nanostructure 250, preventing light extraction efficiency from being reduced as light emitted from active layer 252 of the nanostructure 250 is absorbed by the second electrode 280, and since the second electrode 280 is formed to surround up to a portion of the lateral surface of the nanostructure 250, efficiency of injecting a current into the second conductivity-type semiconductor layer 253 is not reduced. Namely, by the structure of the second electrode 280, light extraction efficiency can be enhanced without reducing efficiency of injecting a current into the second conductivity-type semiconductor layer 253.

However, like the semiconductor light emitting device 100-1 according to the second embodiment example, the semiconductor light emitting device 200 according to the third example may include the ohmic-electrode layer made of ITO and disposed on an upper portion of the nanostructure 250 and an upper portion of the filler 260, and the second electrode formed on an upper surface of the ohmic-electrode layer.

Various examples may be applied to various types of semiconductor light emitting devices having a nanostructure.

Also, as described above, a plurality of openings formed in the insulating layer disclosed in the first to third examples may have different diameters. Hereinafter, the instances in which a plurality of openings have different diameters will now be described.

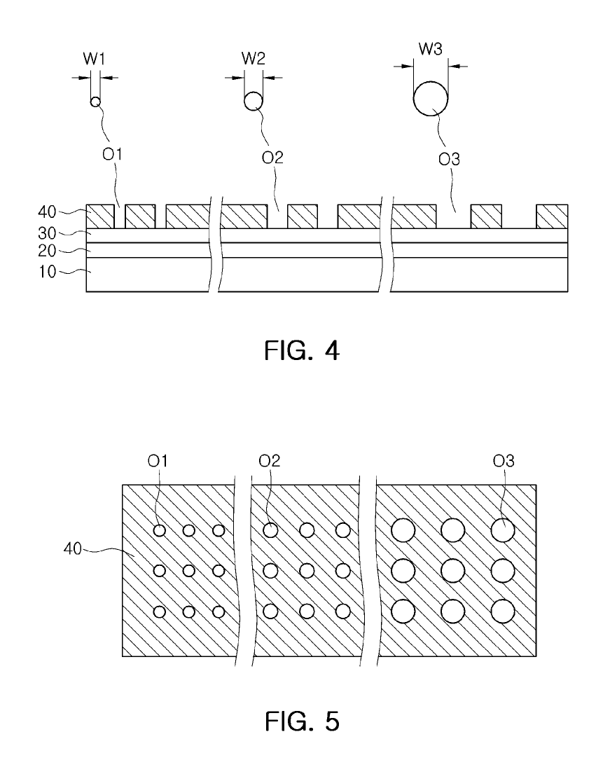

FIG. 4 is a cross-sectional view illustrating an insulating layer 40 including a plurality of openings O1, O2, and O3 having different diameters, and FIG. 5 is a plan view illustrating an insulating layer 40 including a plurality of openings O1, O2, and O3 having different diameters.

FIGS. 4 and 5 illustrate a substrate 10, a buffer layer 20, a first conductivity-type semiconductor base layer 30 formed on the buffer layer 20, and an insulating layer 40 including openings allowing portions of the first conductivity-type semiconductor base layer 30 to be exposed.

Here, the insulating layer 40 may include a plurality of openings O1, O2, and O3 allowing portions of the first conductivity-type semiconductor base layer 30 to be exposed, and having different diameters. The plurality of openings O1, O2, and O3 may have predetermined diameters W1, W2, and W3 and may be formed at predetermined intervals, respectively. The diameters W1, W2, and W3 of the respective openings O1, O2, and O3 illustrated in FIG. 3 are W1<W2<W3 in order.

Also, as illustrated in FIG. 5, the insulating layer 40 may have a plurality of groups including a plurality of openings having the same diameter, and the plurality of groups may have different diameters. The openings O1, O2, and O3 may have various shapes, in addition to a circular shape.

By forming the openings having different diameters, nanostructures having different diameters may be formed on the same substrate, and thus, light beams having various wavelengths may be emitted by the semiconductor light emitting device having the nanostructures having different diameters. Namely, the nanostructures having different diameters and grown under the same growth conditions have different contents of indium (In) and different thicknesses of growth surfaces, emitting light beams having different wavelengths.

Thus, the nanostructures according to the first to third examples may be formed to have different diameters, and thus, the single semiconductor light emitting device may emit light beams having various wavelengths. Also, a semiconductor light emitting device emitting white light by mixing light beams having various wavelengths may be formed. For example, when the insulating layer illustrated in FIGS. 4 and 5 are formed to have openings having different diameters in the semiconductor light emitting device having nanostructures according to the first example illustrated in FIG. 1, nanostructures having different diameters may be formed. Thus, light extraction efficiency can be enhanced by the filler and the electrode structure, and also, a semiconductor light emitting device capable of emitting light beams having various wavelengths can be fabricated.

Also, by adjusting the spaces between the plurality of openings, nanostructures grown under the same growth conditions may have different contents of indium (In) and different thicknesses of growth surfaces. Namely, as the space between openings is increased under the same growth conditions, the content of indium (In) of the nanostructures may be increased and the thickness of the growth surface may be increased. Thus, light beams having different wavelengths may be emitted by adjusting the spaces between the plurality of openings.

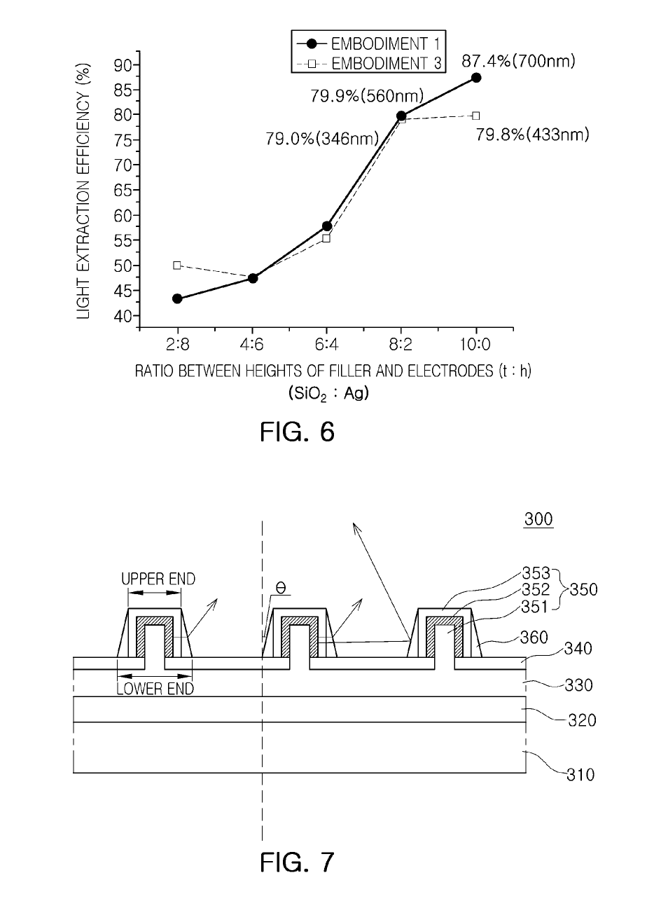

FIG. 6 is a graph showing light extraction efficiency over ratios between fillers provided between nanostructures of a semiconductor light emitting devices and heights of electrodes formed on upper portions of the fillers according to the first and third examples.

Embodiment 1 is a graph showing light extraction efficiency in a case in which a nanostructure has a nanorod shape and has a height of 700 nm, and Embodiment 3 is a graph showing light extraction efficiency in a case in which a nanostructure has a pyramid shape and has a height of 433 nm.

FIG. 6 is a graph showing light extraction efficiency when a ratio (t:h) between the height t of the filler and the height h, of the electrode formed on the upper portion of the filler, from an upper portion of the filler to an upper portion of the nanostructure in Embodiment 1 and Embodiment 3 is 2:8, 4:6, 6:4, 8:2, and 10:0, respectively. Here, SiO₂ was used as the filler and silver (Ag) was used as the electrode.

As illustrated in FIG. 6, it can be seen that as the height t of the filler is increased, light extraction efficiency is increased. In particular, light extraction efficiency was high in the case in which the ratio (t:h) between the height t of the filer and the height h of the electrode formed on an upper portion of the filler from the upper portion of the filler to an upper portion of the nanostructure is 6:4 or greater.

Also, in Embodiment 3, in the case in which the ratio (t:h) between the height t of the filer and the height h of the electrode formed on an upper portion of the filler from the upper portion of the filler to an upper portion of the nanostructure is 6:4 or greater, namely, in the case in which the height t of the filler is approximately ⅗ or more of the height (t+h) of the nanostructure, light extraction efficiency is high, relative to the case in which the ratio (t:h) between the height t of the filer and the height h of the electrode formed on an upper portion of the filler from the upper portion of the filler to an upper portion of the nanostructure is 2:8, namely, in the case in which the height t of the filler is approximately ⅕ of the height (t+h) of the nanostructure.

Thus, in the semiconductor light emitting device having a nanostructure, when the height t of the filler is approximately ⅗ or more of the height (t+h) of the nanostructure and the height h of the electrode formed in the upper portion of the nanostructure and the upper portion of the filler between the nanostructures is approximately ⅖ or less, high light extraction efficiency is high and a semiconductor light emitting device having excellent current injection efficiency can be obtained.

FIG. 7 is a cross-sectional view of a semiconductor light emitting device including nanostructures according to a fourth example.

Referring to FIG. 7, a semiconductor light emitting device 300 according to a fourth examples includes a substrate 310, a first conductivity-type semiconductor base layer 330, an insulating layer 340, a nanostructure 350 including a first conductivity-type semiconductor layer core 351 extending from the first conductivity-type semiconductor base layer 330, an active layer 352, and a second conductivity-type semiconductor layer 353, and a laterally sloped layer 360 formed on a lateral surface of the nanostructure 350 to form a sloped surface.

The substrate 310, provided as a semiconductor growth substrate, may be formed of one material selected from a group consisting of sapphire, SiC, MgAl₂O₄, MgO, LiAlO₂, LiGaO₂ and GaN. In case of a sapphire substrate commonly used as a nitride semiconductor growth substrate, sapphire may be a crystal having Hexa-Rhombo R3c symmetry, may have respective lattice constants of 13.001 Å and 4.758 Å in c-axis and a-axis directions, and may have a C (0001) plane, an A (1120) plane, an R (1102) plane and the like. In this case, since the C plane comparatively facilitates the growth of a nitride thin film and is stable at relatively high temperatures, the C plane may be mainly used as a growth substrate for a nitride semiconductor. Meanwhile, a silicon (Si) substrate may also be used as the substrate 310. The use of a silicon substrate, which should have a large diameter and be relatively low in price, may facilitate mass-production. In the case in which a silicon substrate is used, a nucleation layer made of AlxGa1-xN may be formed on the substrate 310 and a nitride semiconductor having a desired structure may be grown thereon.

A buffer layer 320 may be formed on the substrate 310. The buffer layer 320 may be formed to alleviate lattice mismatching between the substrate 310 and the first conductivity-type semiconductor base layer 330. The buffer layer 120 may be formed at a relatively low temperature without doping. The buffer layer 120 may be omitted.

The first conductivity-type semiconductor base layer 330 may be formed on the substrate 310 or the buffer layer 320. The first conductivity-type semiconductor base layer 330 may be formed of a group III-V compound. The first conductivity-type semiconductor base layer 330 may be formed of gallium nitride (GaN). The first conductivity-type semiconductor base layer 330 may be formed by n-doping. Here, n-doping refers to a doping using a group V element. The first conductivity-type semiconductor base layer 330 may be an n-GaN layer. Electrons may be transferred to the active layer through the first conductivity-type semiconductor base layer 330.

The insulating layer 340 may be formed on the first conductivity-type semiconductor base layer 330. The insulating layer 340 may be made of a silicon oxide or a silicon nitride. The insulating layer 340 may include openings allowing portions of the first conductivity-type semiconductor base layer 330 to be exposed. Cross sections of the nanostructures may vary according to shapes of the openings of the insulating layer 340. The openings may have various shapes, in addition to a circular shape. The plurality of openings may have different diameters. When the plurality of openings are formed to have different diameters, a semiconductor light emitting device having nanostructures having different diameters on the same substrate may emit light beams having various wavelengths.

Subsequently, the nanostructure 350 having a nanorod shape including the first conductivity-type semiconductor layer core 351, the active layer 351 and the second conductivity-type semiconductor layer 353 may be formed, and in this case, a plurality of nanostructures may be provided. A lateral surface of the nanostructure 350 has a slope perpendicular to the substrate.

Hereinafter, the first conductivity-type semiconductor layer core 351, the active layer 352, and the second conductivity-type semiconductor layer 353 will be described.

The first conductivity-type semiconductor layer core 351 extends from the exposed first conductivity-type semiconductor base layer 330. The first conductivity-type semiconductor layer core 351 may be formed by growing the first conductivity-type semiconductor base layer 330. A cross-section of the first conductivity-type semiconductor layer core 351 may have a circular shape or a polygonal shape.

Next, the active layer 352 may be formed to cover the first conductivity-type semiconductor layer core 351. Here, the active layer 352 may cover an upper surface and lateral surfaces of the first conductivity-type semiconductor layer core 351. The active layer 352 may be a layer formed of a single material such as InGan or the like, but may also have the MQW structure in which a quantum barrier layer and a quantum well layer are alternately disposed, which are formed of, for example, Gan and InGan, respectively. In the active layer 352, light energy may be generated through the combination of electrons and holes.

The second conductivity-type semiconductor layer 353 may be formed to surround the active layer 352. The second conductivity-type semiconductor layer 353 may cover an upper surface and lateral surfaces of the active layer 352. The second conductivity-type semiconductor layer 353 may be a group III-V compound layer. The second conductivity-type semiconductor layer 353 may be p-doped. Here, p-doping may refer to a doping using a group III element. In addition, the second conductivity-type semiconductor layer 353 may be doped with a magnesium (Mg) impurity. The second conductivity-type semiconductor layer 353 may be a GaN layer or an InGaN layer. The second conductivity-type semiconductor layer 353 may be a p-GaN layer or a p-InGaN layer. Holes may move to the active layer 352 through the second conductivity-type semiconductor layer 353.

In the present example, the laterally sloped layer 360 may be formed on a lateral surface of nanostructure 350 having a nanorod shape, whereby the lateral surfaces of the light emitting unit including the first conductivity-type semiconductor layer core 351, the active layer 352, the second conductivity-type semiconductor layer 353, and the laterally sloped layer 360 is sloped with respect to an upper surface of the substrate.

Namely, the lateral surface of the light emitting unit including the laterally sloped layer 360 may have a shape in which it is sloped with respect to a direction perpendicular to the substrate by a predetermined angle (θ). The lateral surface of the light emitting unit may be sloped at an angle (θ) greater than 0° and less than 45° with respect to a direction perpendicular to the substrate. Thus, an internal angle formed by a lateral surface of the light emitting unit and an upper surface of the substrate may be greater than 45° and less than 90°.

The laterally sloped layer 360 may be formed to surround a side wall of the vertically shaped second conductivity-type semiconductor layer 353. Thus, the light emitting unit including the laterally sloped layer 360 may have a shape in which a lower portion thereof is relatively wide and an upper portion thereof is relatively narrow. The light emitting unit may have a trapezoidal shape, when viewed from the side.

As such, when the lateral surface of the light emitting unit having the laterally sloped layer 360 is sloped with respect to the upper surface of the substrate, light emitted from the active layer 352 may be refracted from a sloped lateral surface of the light emitting unit or reflected from the sloped lateral surface of a light emitting unit adjacent thereto, such that the light may be emitted upwardly or downwardly from the light emitting device, enhancing light extraction efficiency.

However, in a case in which the lateral surface of the light emitting unit is sloped with respect to the direction perpendicular to the substrate by an angle (θ) equal to or greater than 45°, namely, when an internal angle formed by the lateral surface of the light emitting unit and the upper surface of the substrate is equal to or lower than 45°, an area of the active layer may be reduced to secure a space for forming the laterally sloped layer, rather lowering light efficiency. Thus, the angle θ sloped with respect to the direction perpendicular to the substrate may be greater than 0° and less than 45°. Accordingly, the internal angle formed by the lateral surface of the light emitting unit and the upper surface of the substrate may be greater than 45° and less than 90°.

The laterally sloped layer 360 may be formed of the same material as that of the second conductivity-type semiconductor layer 353. Thus, the laterally sloped layer 360 may be formed simultaneously with the second conductivity-type semiconductor layer 70 at the time of forming the second conductivity-type semiconductor layer 70. When the second conductivity-type semiconductor layer 353 is made of p-InGaN, the laterally sloped layer 360 may be made of p-InGaN.

However, the second conductivity-type semiconductor layer 353 and the laterally sloped layer 360 may not be simultaneously formed, but may be sequentially formed.

In addition, the laterally sloped layer 360 may also be formed by depositing a material different from that of the second conductivity-type semiconductor layer 353 in consideration of light extraction efficiency. Here, the laterally sloped layer 360 may be formed of a transparent material. The laterally sloped layer 360 may be formed of a silicon oxide, a silicon nitride, or an oxide. For example, the laterally sloped layer 360 may be formed of a silicon oxide (SiO₂), a silicon nitride (SiN) or an oxide (Indium Tin Oxide (ITO), ZnO, IZO (ZnO:In), AZO (ZnO:Al), GZO (ZnO:Ga), In₂O₃, SnO₂, CdO, CdSnO₄, Ga₂O₃, or TiO₂).

Electrodes required for the semiconductor light emitting device formed thusly may be formed to have various shapes. Also, the fillers and the electrodes according to the first to the third examples may be formed in the semiconductor light emitting device having the nanostructures formed thusly. For example, a semiconductor light emitting device having further enhanced light extraction efficiency may be formed by combining the fourth example of FIG. 7 to the first example of FIG. 1.

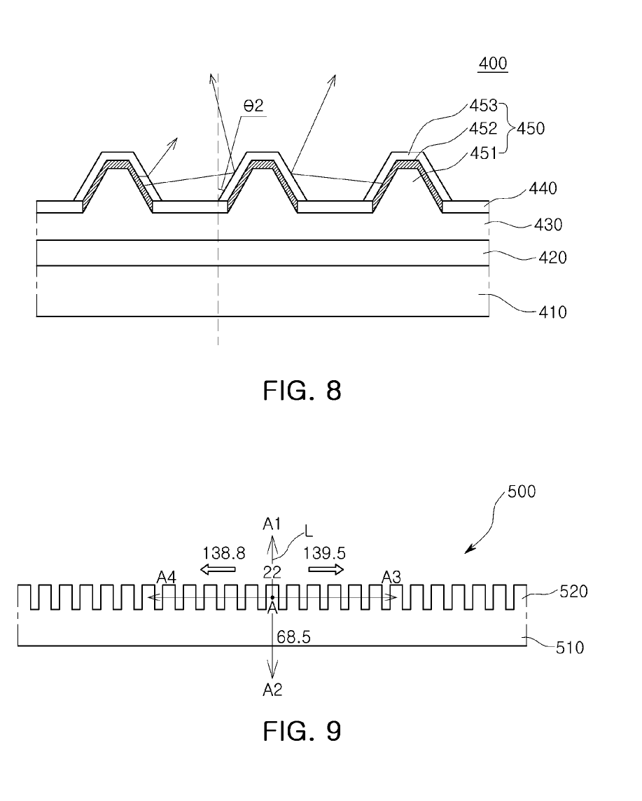

FIG. 8 is a cross-sectional view of a semiconductor light emitting device including nanostructures according to a fifth example. Hereinafter, descriptions of the same elements as those of the embodiment described above with reference to FIG. 7 will be omitted, and different elements will be described.

Referring to FIG. 8, a semiconductor light emitting device 400 may include a nanostructure 450 including a first conductivity-type semiconductor layer core 451, an active layer 452 and a second conductivity-type semiconductor layer 453.

Unlike the fourth example, in the present example, lateral surfaces of the nanostructure including the first conductivity-type semiconductor layer core 451, the active layer 452, and the second conductivity-type semiconductor layer 453 are sloped with respect to an upper surface of the substrate.

Namely, respective lateral surfaces of the first conductivity-type semiconductor layer core 451, the active layer 452, and the second conductivity-type semiconductor layer 453 may be sloped with respect to a direction perpendicular to the substrate at a predetermined angle (θ2). Preferably, the respective lateral surfaces of the first conductivity-type semiconductor layer core 451, the active layer 452, and the second conductivity-type semiconductor layer 453 may be sloped at an angle (θ2) greater than 0° and less than 45° with respect to a direction perpendicular to the substrate.

In detail, the nanostructure may have a shape in which a lower portion thereof is relatively wide and an upper portion thereof is relatively narrow. The light emitting unit may have a trapezoidal shape, when viewed from the side.

As such, when the lateral surface of the nanostructure including the active layer 452 is sloped with respect to the upper surface of the substrate, light emitted from the active layer 452 may be refracted from the sloped lateral surfaces of the light emitting unit (nanostructure: 450) or may be reflected from an sloped lateral surface of a light emitting unit adjacent thereto, such that the light may be emitted upwardly or downwardly from the light emitting device, enhancing light extraction efficiency.

However, in a case in which the lateral surface of the nanostructure 450 is sloped with respect to the direction perpendicular to the substrate by the angle (θ2) equal to or greater than 45°, namely, when an internal angle formed by the lateral surface of the nanostructure 450 and the upper surface of the substrate 410 is equal to or lower than 45°, an area of the active layer may be reduced to degrade light efficiency. Thus, the angle (θ2) sloped with respect to the direction perpendicular to the substrate 410 may be greater than 0° and less than 45°. Accordingly, the internal angle formed by the lateral surface of the nanostructure 450 and the upper surface of the substrate 410 may be greater than 45° and less than 90°.

Electrodes required for the semiconductor light emitting device formed thusly may be formed to have various shapes. Also, the fillers and the electrodes according to the first to the third examples may be formed in the semiconductor light emitting device having the nanostructures formed thusly. For example, a semiconductor light emitting device having further enhanced light extraction efficiency may be formed by combining the fifth example of FIG. 8 to the first example of FIG. 1.

Hereinafter, operational effects of the semiconductor light emitting device according to the fourth and fifth examples will be described in more detail with reference to the accompanying drawings.

FIG. 9 is a cross-sectional view illustrating the intensity of light according to respective directions of light L emitted from the point A of a semiconductor light emitting device 500 having a light emitting unit having a lateral surface perpendicular with respect to the substrate.

As shown in FIG. 9, the light L emitted laterally from the semiconductor light emitting device 500 having the light emitting unit (nanostructure) 520 perpendicular with respect to the substrate 510 may be emitted in all directions including upwardly, downwardly, and horizontally.

Numerals represented in FIG. 9 indicate the relative intensity of light emitted in respective directions. Here, the intensity of emitted light L was measured schematically, separately, in upward, downward and horizontal directions.

As shown in FIG. 9, the light L emitted laterally from the point A is emitted even upward (A1) and downward (A2) directions, as well as in the horizontal directions A3 and A4.

However, in order for the light L emitted laterally to contribute to the light extraction efficiency of the semiconductor light emitting device, the light L is required to be emitted upwardly or downwardly from the semiconductor light emitting device 500 and, the light L emitted in the horizontal directions A3 and A4 is required to be emitted upwardly or downwardly through reflection and refraction so as to contribute to the light extraction efficiency of the semiconductor light emitting device.

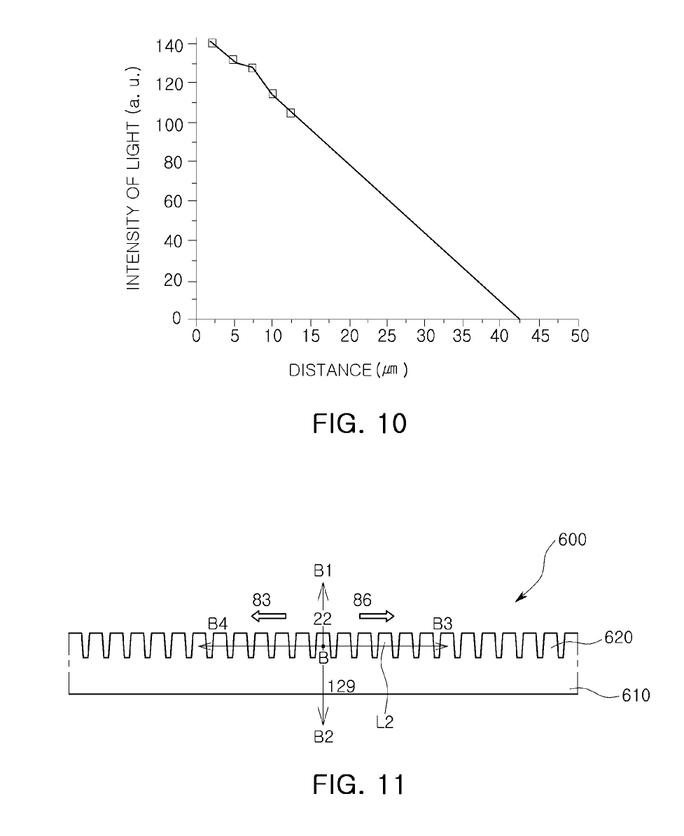

FIG. 10 is a graph illustrating the intensity of light according to a light emission distance of the light L emitted from the point A of the semiconductor light emitting device of FIG. 9 in the horizontal direction.

As shown in FIG. 10, the light L emitted in the horizontal direction may not be detected at a distance of around 45 μm or more, which indicates that the light L emitted from the point A of the light emitting unit moves in the horizontal direction without contributing to light extraction efficiency until the light L has passed the distance of around 45 μm.

Thus, it can be seen that the light L emitted in the horizontal directions A3 and A4 from the semiconductor light emitting device 500 needs to be emitted for a relatively prolonged distance until the light L is emitted upwardly or downwardly from the semiconductor light emitting device 300 in order to contribute to the light extraction efficiency of the semiconductor light emitting device.

As such, in the light L emitted from the point A, since light emitted in the horizontal directions A3 and A4 is emitted by a relatively prolonged distance until it is emitted upwardly or downwardly from the semiconductor light emitting device 500, a relatively large amount of light may be absorbed and lost during the emission in the horizontal directions due to the light emitting unit 320 and materials formed between a plurality of the light emitting unit 500 in the semiconductor light emitting device 500. Thus, light extraction efficiency of the light L emitted from the semiconductor light emitting device 500 may be deteriorated.

FIG. 11 is a cross-sectional view illustrating the intensity of light according to respective directions of light L2 emitted from a point B of a semiconductor light emitting device 600 having a light emitting unit (nanostructure) 620 having a lateral surface sloped at a predetermined angle with respect to an upper surface of a substrate.

As shown in FIG. 11, the light L2 emitted from the point B of the semiconductor light emitting device 600 having the light emitting unit 620 having a lateral surface sloped at a predetermined angle with respect to an upper surface of a substrate 610 may be emitted in the overall direction including upper, lower and horizontal directions.

Numerals represented in FIG. 11 indicate the intensity of the light L2 emitted in respective directions. Here, the intensity of emitted light L2 was measured schematically, separately, in upward, downward, and horizontal directions.

As shown in FIG. 11, it can be seen that a larger amount of the light L2 laterally emitted from the point B is emitted in the lower direction B2 than in the horizontal directions B3 and B4 as compared with that of FIG. 9.

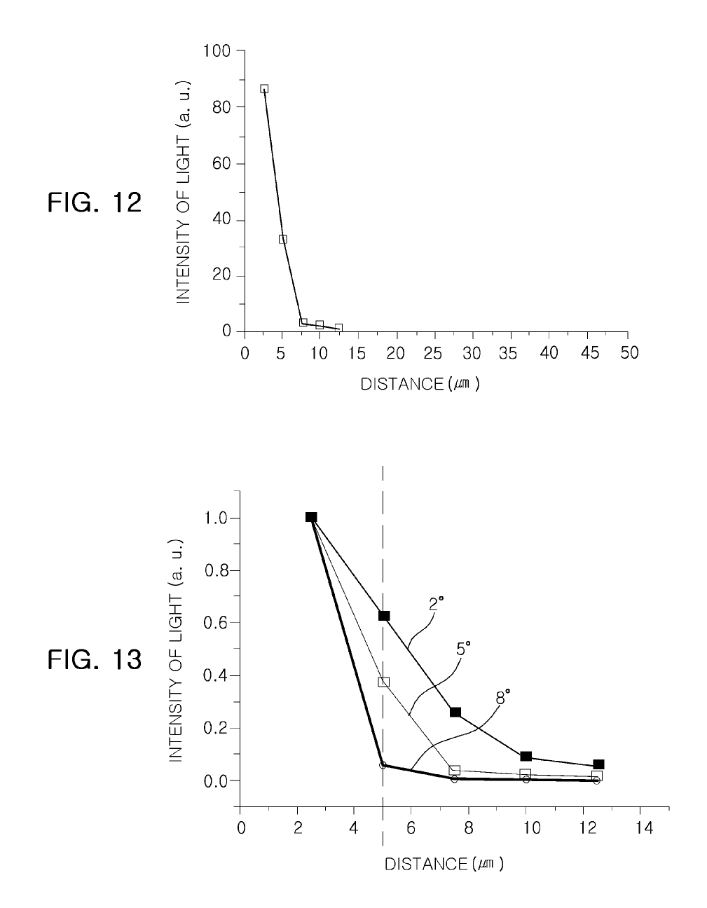

FIG. 12 is a graph illustrating the intensity of light according to a light emission distance of the light L2 emitted from the point B of the semiconductor light emitting device of FIG. 11 in the horizontal direction.

As shown in FIG. 12, light emitted in the horizontal directions is not detected at a distance of around 10 μm. This indicates that the light L2 emitted in the horizontal directions has contributed to the light extraction efficiency soon. Thus, it can be appreciated that the light has been emitted upwardly or downwardly from the light emitting device.

As described above, lateral surfaces of the plurality of light emitting units of a semiconductor light emitting device may be sloped with respect to an upper surface of a substrate to reduce a horizontal component in laterally emitted light, to thus enhance light extraction efficiency.

FIG. 13 is a graph illustrating the strength of light emitted from a point of a semiconductor light emitting device in horizontal directions according to emission distances of light for each inclination of respective light emitting units.

Namely, the strength of light emitted in the horizontal directions according to emission distances of light is provided based on the extent of an inclination in which a lateral surface of the light emitting unit of the semiconductor light emitting device is sloped with respect to a direction perpendicular to the substrate.

As shown in FIG. 13, it can be appreciated that as the inclination of the lateral surface of the light emitting unit with respect to the direction perpendicular to the substrate increases and an internal angle formed by the upper surface of the substrate and the lateral surface of the light emitting unit decreases, in a case in which distances from the light emitting units are the same as one another, the strength of light is relatively low. Namely, it can be seen that in a case in which the strength of light emitted from one point of the semiconductor light emitting device is measured at a distance of 5 μm, the strength of light is relatively low in the case of being sloped by 5° than in the case of being sloped by 2° and in the case of being sloped by 8° than in the case of being sloped by 5°.

This indicates that as the inclination of the lateral surface of the light emitting unit with respect to the direction perpendicular to the substrate is higher, namely, in the case that an internal angle formed by the upper surface of the substrate and the lateral surface of the light emitting unit is lower; a larger amount of light laterally emitted from the semiconductor light emitting device may be extracted from an upper portion or a lower portion of the semiconductor light emitting device.

However, in a case in which the inclination of the light emitting unit with respect to the direction perpendicular to the substrate is equal to or greater than 45°, since the possibility of a total reflection of light inside the light emitting unit may increase and an area of the active layer may be reduced, the inclination of the lateral surface of the light emitting unit with respect to the direction perpendicular to the substrate may be greater than 0° and less than 45°.

As described above, in a nanorod-based light emitting device according to certain examples, a lateral surface of the light emitting unit may be sloped at a predetermined angle with respect to an upper surface of the substrate, whereby light extraction efficiency may be improved.

Hereinafter, a semiconductor light emitting device having nanostructures according to a sixth example of the present application will be described.

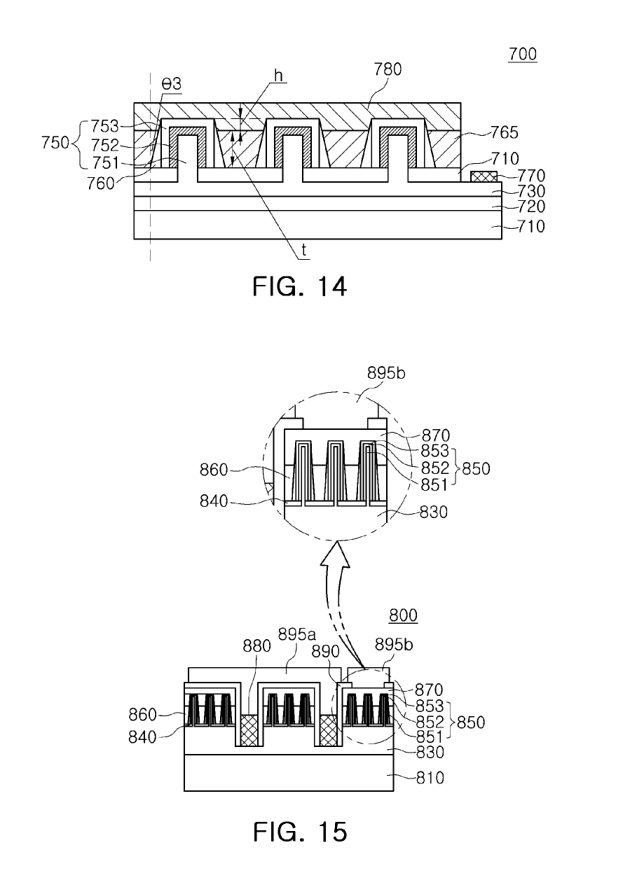

FIG. 14 is a cross-sectional view illustrating a semiconductor light emitting device according to a sixth embodiment of the present invention. The semiconductor light emitting device having a nanostructure according to the sixth embodiment of the present invention is a flip-chip type semiconductor light emitting device. However, in FIG. 14, the flip-chip type semiconductor light emitting device is illustrated to have a substrate thereof placed in a lower side.

As illustrated in FIG. 14, the semiconductor light emitting device according to the sixth example has the same components as those of the semiconductor light emitting device according to the first example illustrated in FIG. 1, except for the presence of a laterally sloped layer 760. Thus, descriptions of the same components will be omitted.

Referring to FIG. 14, the semiconductor light emitting device 700 according to the sixth example includes a substrate 710, a buffer layer 720, a first conductivity-type semiconductor base layer 730 formed on the substrate 710 or the buffer layer 720, an insulating layer 740, a nanostructure 750 including a first conductivity-type semiconductor layer core 751, an active layer 752, and a second conductivity-type semiconductor layer 753, a laterally sloped layer 760 formed on a lateral surface of the nanostructure 750 to form a sloped surface, a filler 765 filling spaces between the nanostructures 750 with the laterally sloped layer 760 formed on a lateral surface thereof, a first electrode 770 formed on an exposed upper surface of the first conductivity-type semiconductor base layer 730, and a second electrode 780 formed on upper portions of the nanostructures 750 and an upper portion of the filler 765.

In the present example, the lateral surfaces of the light emitting unit including the first conductivity-type semiconductor layer core 751, the active layer 752, the second conductivity-type semiconductor layer 753, and the laterally sloped layer 760 is sloped with respect to an upper surface of the substrate by the laterally sloped layer 760.

Namely, the lateral surface of the light emitting unit including the laterally sloped layer 760 may have a shape in which it is sloped with respect to a direction perpendicular to the substrate by a predetermined angle (θ3). The lateral surface of the light emitting unit may be sloped at an angle (θ3) greater than 0° and less than 45° with respect to a direction perpendicular to the substrate. Thus, an internal angle formed by the lateral surface of the light emitting unit and an upper surface of the substrate may be greater than 45° and less than 90°.

The laterally sloped layer 760 may be formed to surround a side wall of the vertically shaped second conductivity-type semiconductor layer 353. Thus, the light emitting unit including the laterally sloped layer 760 may have a shape in which a lower portion thereof is relatively wide and an upper portion thereof is relatively narrow. The light emitting unit may have a trapezoidal shape, when viewed from the side.

As such, when the lateral surface of the light emitting unit having the laterally sloped layer 760 is sloped with respect to the upper surface of the substrate, light emitted from the active layer 752 may be refracted from the sloped lateral surface of the light emitting unit or reflected from a sloped lateral surface of a light emitting unit adjacent thereto, such that the light may be emitted upwardly or downwardly from the light emitting device, enhancing light extraction efficiency.

Also, the filler 765 formed between the nanostructures and disposed on the insulating layer 740 may have a height t lower than an upper surface of the nanostructure 750. Also, the filler 765 may be formed to be approximately ⅗ or more of the height (h+t) of the nanostructure 750. The filler 765 may serve to effectively emit light generated by the active layer 752 outwardly, further enhancing a light output of the light emitting device.

The second electrode 780 may be formed on an upper portion of the nanostructure 750 and an upper portion of the filler 765 and may be electrically connected to the second conductivity-type semiconductor layer 753. The second electrode 780 may be a reflective electrode. Namely, the second electrode 780 may be made of a light reflective material, e.g., a highly reflective metal, and in this case, in the light emitting device 700, the first and second electrodes 770 and 780 may be mounted toward a lead frame, or the like, of the package. Thus, a partial amount of light emitted from the active layer 752 of the nanostructure 750 may be absorbed by the second electrode 780 and another partial amount of light may be reflected by the second electrode 780 and emitted in a direction toward the substrate 710.

A height h of the second electrode 780 between nanostructures 750 is approximately ⅖ or less of the height (h+t) of the nanostructure 750. Namely, since the second electrode 780 is formed to only cover a portion of the lateral surface of the nanostructure 750, absorption of light emitted from active layer 752 of the nanostructure 750 by the second electrode 780 is reduced, and since the second electrode 780 is formed to surround up to a portion of the lateral surface of the nanostructure 750, efficiency of injecting a current into the second conductivity-type semiconductor layer 753 is not reduced. Namely, by the structure of the second electrode 780, light extraction efficiency can be enhanced without reducing efficiency of injecting a current into the second conductivity-type semiconductor layer 753.

In this manner, by virtue of the structure of the laterally sloped layer 760, the filler 765, and the second electrode 780 formed on an upper portion of the filler 765, the semiconductor light emitting device according to the present embodiment can have enhanced light extraction efficiency.

FIG. 15 is a cross-sectional view illustrating a semiconductor light emitting device according to a seventh example.

Referring to FIG. 15, the semiconductor light emitting device 800 according to the seventh example includes a first conductivity-type semiconductor base layer 830 formed on a substrate 810, an insulating layer 840, a nanostructure 850 including a first conductivity-type semiconductor layer core 851 extending from the first conductivity-type semiconductor base layer 830, an active layer 852, and a second conductivity-type semiconductor layer 853, and a filler 860 filling spaces between the nanostructures 850. Also, the semiconductor light emitting device 800 according to the seventh example includes first and second internal electrodes 880 and 870 and first and second pad electrodes 895a and 895b.

In the present example, the first conductivity-type semiconductor base layer 830 may be an n-type semiconductor layer and the second conductivity-type semiconductor layer 853 may be a p-type semiconductor layer.

The filler 860 having a predetermined refractive index may be formed between the nanostructures 850. Here, the filler 860 may be made of a material having a refractive index equal to or lower than that of the nanostructure 850. For example, the refractive index of the filler 860 may range from 1 to 2.5. Also, the filler 860 may be made of a light-transmissive material in a functional aspect.

Here, the filler 860 may have a height t lower than the nanostructure 850. However, if the filler 860 is too low, the second internal electrode 870 to be formed on the nanostructure 850 afterwards may excessively surround the nanostructure 850, making light emitted from the active layer 852 absorbed by the second internal electrode 870, reducing light extraction efficiency. Thus, the filler 860 may be formed to be approximately ⅗ or more of the height (h+t) of the nanostructure 850.

Thus, the filler 860 may serve to effectively emit light generated by the active layer 852 outwardly, further enhancing a light output of the light emitting device.

Here, a height h of the second internal electrode 870 between nanostructures 850 is approximately ⅖ or less of the height (h+t) of the nanostructure 850. Namely, since the second internal electrode 870 is formed to only cover a portion of the lateral surface of the nanostructure 850, absorption of light emitted from active layer 852 of the nanostructure 850 by the second internal electrode 870 is reduced, and since the second internal electrode 870 is formed to surround up to a portion of the lateral surface of the nanostructure 850, efficiency of injecting a current into the second conductivity-type semiconductor layer 853 is not reduced. Namely, by the structure of the second internal electrode 870, light extraction efficiency can be enhanced without reducing efficiency of injecting a current into the second conductivity-type semiconductor layer 853.

The first internal electrode 880 may be formed to fill a portion of a groove formed as a portion of the nanostructure 850 is removed, and connected to the first conductivity-type semiconductor base layer 830 and may have shape corresponding to the groove. However, unlike the present example, in order to form a groove allowing the first conductivity-type semiconductor base layer 830 to be exposed therethrough, the first conductivity-type semiconductor base layer 830 may not be removed, and in this case, the first internal electrode 880 may be in contact with the uppermost surface of the first conductivity-type semiconductor base layer 830. Meanwhile, when a groove is formed by removing a portion of the nanostructure 850, a lateral surface of the groove may be a sloped surface, and in this case, the lateral surface of the groove may not be formed as a sloped surface according to a method of removing the nanostructure 850.

Also, the first internal electrode 880 may be surrounded by the insulating unit 890 so as to be electrically separated from the nanostructure 850. Also, at least a portion of the insulating unit 890 may be exposed so as to be connected to the first pad electrode 895a and the other portions of the first internal electrode 880 may be covered so as not to be exposed.

The insulating unit 890 fills a portion of the groove to prevent the first internal electrode 880 from being connected to the nanostructure 850, and the insulating unit 890 may also be formed on the first and second internal electrodes 880 and 870 to separate them. In this case, the insulating unit 890 may have open regions allowing at least portions of the first and second internal electrodes 880 and 870 to be exposed therethrough, and the first and second pad electrodes 895a and 895b may be formed in the open regions. In consideration of such a function, the insulating unit 890 may be made of any material as long as it has electrically insulating properties. For example, the insulating unit 890 may be made of an electrically insulating material such as a silicon oxide, a silicon nitride, or the like. Also, a light reflective filler may be dispersed in the electrically insulating material to form a light reflective structure.

The first and second pad electrodes 895a and 895b may be connected to the first and second internal electrodes 880 and 870 and serve as external terminals of the light emitting device 800. The first and second pad electrodes 895a and 895b may be formed as a single layer or two or more layers, respectively. The first and second pad electrodes 895a and 895b may be obtained by performing a method such as deposition, sputtering, plating, or the like, on a single metal such as silver (Ag), aluminum (Al), nickel (Ni), chromium (Cr), palladium (Pd), copper (Cu), or the like, or an alloy thereof. Also, the first and second pad electrodes 895a and 895b may include eutectic metal, for example, a material such as AuSn, SnBi, or the like, and in this case, when mounted on a package, or the like, the first and second pad electrodes 895a and 895b may be bonded through eutectic bonding, eliminating the use of solder bumps generally required for bonding a flip chip. The mounting method using eutectic metal has a superior advantage of a heat dissipation effect to the case of using solder bumps. In this case, in order to obtain an excellent heat dissipation effect, the first and second pad electrodes 895a and 895b may be formed to occupy a relatively large area. Specifically, an area occupied by the first and second pad electrodes 895a and 895b may be 80% to 95% of the area of the upper surface.

In the present example, the nanostructure 850 is provided, and the laterally sloped layer 860 is formed on the lateral surface of the nanostructure 850 to enhance light extraction efficiency. Also, light extraction efficiency may be further enhanced by the second internal electrode 870 surrounding portions of the filler 860 formed between the nanostructures 850 and portions of the nanostructure 850.

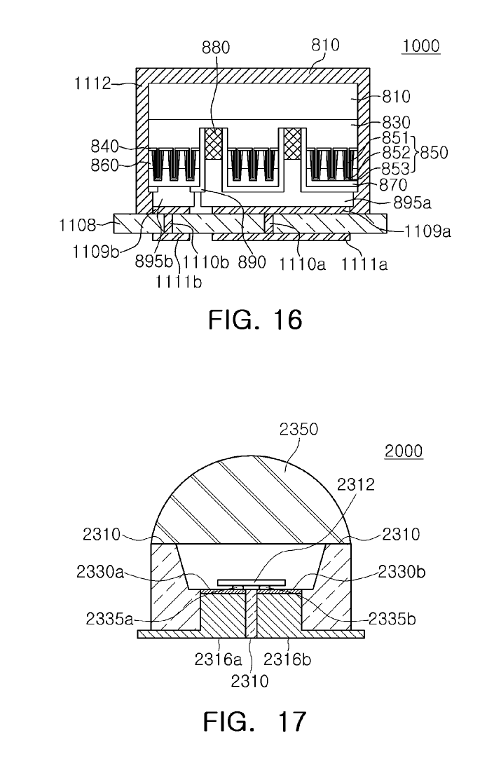

FIG. 16 is a view illustrating an example of the application of the semiconductor light emitting device of FIG. 15 to a package. A light emitting device package 1000 illustrated in FIG. 16 includes a mounting board 1108 and a semiconductor light emitting device mounted thereon. The semiconductor light emitting device may have the foregoing structure. The mounting board 1108 may include first and second upper surface electrodes 1109a and 1109b and first and second lower surface electrodes 1111a and 1111b. The first and second upper surface electrodes 1109a and 1109b and the first and second lower surface electrodes 1111a and 1111b may be connected by first and second through electrodes 1110a and 1110b. Such a structure of the mounting board 1108 is merely an example, and may be applied in various forms. Also, the mounting board 1108 may be provided as a circuit board such as a PCB, an MCPCB, an MPCB, an FPCB, or the like, or a ceramic board made of AlN, Al₂O₃, or the like. The mounting board 1108 may also be provided as a lead frame of a package, rather than as a board.

Meanwhile, the semiconductor light emitting device is disposed in a flip chip form, namely, the semiconductor light emitting device is disposed in a direction in which the first and second pad electrodes 895a and 895b face the mounting board 1108. The first and second pad electrodes 895a and 895b may include a bonding layer, e.g., a eutectic metal layer formed on a surface thereof, whereby the first and second pad electrodes 895a and 895b may be bonded to the first and second upper surface electrodes 1109a and 1109b. In this case, if the first and second pad electrodes 895a and 895b do not have a bonding layer, a bonding layer, e.g., a eutectic metal layer, conductive epoxy, or the like, may be formed between the first and second pad electrodes 895a and 895b and the first and second upper surface electrodes 1109a and 1109b. Meanwhile, although not an essential component in the present example, a wavelength conversion unit 1112 converting a wavelength of light emitted from the light emitting device into a different wavelength may be formed on a surface of the light emitting device as illustrated in FIG. 16, and to this end, the wavelength conversion unit 1112 may include phosphors, quantum dots, and the like.

FIG. 17 is a view illustrating an example of the application of a semiconductor light emitting device to a package. A light emitting device package 2000 illustrated in FIG. 17 includes a light emitting device 2312, and first and second electrodes 2316a and 2316b provided below the light emitting device 2312. The light emitting device 2312 is attached to the first and second electrodes 2316a and 2316b.

Here, the light emitting device 2312 may be a semiconductor light emitting device according to various examples of the present application. The light emitting device 2312 may be attached to the first and second electrodes 2316a and 2316b through flip chip bonding.

The first and second electrodes 2316a and 2316b may be provided to be spaced apart from one another, apply a voltage to the light emitting device 2312, and serve to dissipate heat generated by the light emitting device 2312. To this end, bonding metals 2335a and 2335b are interposed between the light emitting device 2312 and the first electrode 2316a and between the light emitting device 2312 and the second electrode 2316, respectively.

Here, the bonding metals 2335a and 2335b may be solder made of a gold (Au)-tin (Sn) alloy, a tin (Sn)-silver (Ag) alloy, or the like, or a metal such as gold (Au), copper (Cu), or the like. Meanwhile, the light emitting device 2312 may be attached to the first and second electrodes 2316a and 2316b by a conductive adhesive.

Reflective layers 2330a and 2330b may be coated on surfaces of the first and second electrodes 2316a and 2316b to which the light emitting device 2312 is attached, in order to reflect light generated by the light emitting device 2312 to allow light to move upwardly from the light emitting device 2312. Here, the reflective layers 2330a and 2330b may be made of silver (Ag), aluminum (Al), or the like.

The first and second electrodes 2316a and 2316b are supported by a package housing 2310. Here, the package housing 2310 may be made of a material stable at high temperatures or an insulating material having heat resistance, such as ceramic, or the like. Meanwhile, the package housing 2310 may also be provided between the first and second electrodes 2316a and 2316b to electrically insulate the first and second electrodes 2316a and 2316b. A lens 2350 may be formed above the package housing 2310 in order to collect or distribute light generated by the light emitting device 2312. As illustrated, the lens 2350 may be a dome type lens, but the present application is not limited thereto and various types of lenses such as a flat lens, or the like, may be used.

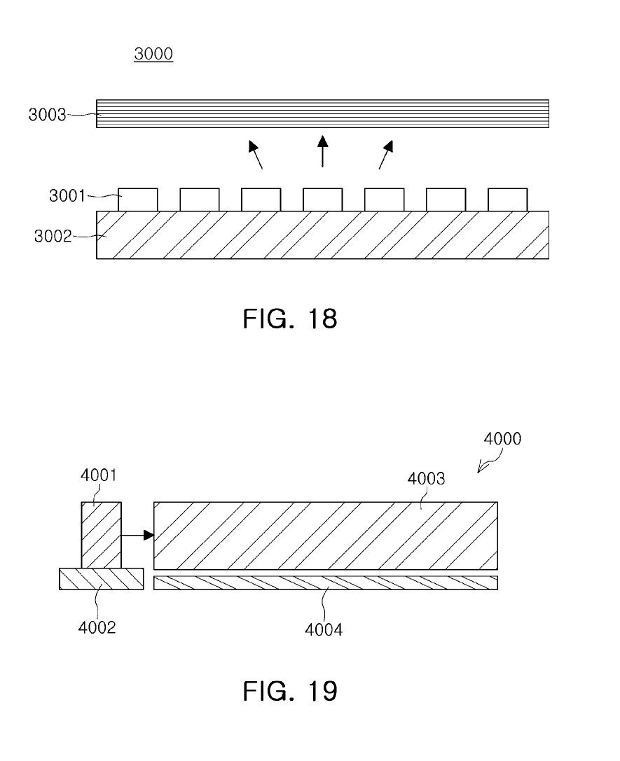

FIGS. 18 and 19 are views illustrating examples of applications of a semiconductor light emitting device to a backlight unit. Referring to FIG. 18, a backlight unit 3000 includes light sources 3001 mounted on a substrate 3002 and one or more optical sheets 3003 disposed above the light sources 3001. As the light source 3001, a light emitting device package having the foregoing structure or a similar structure may be used, or alternatively, a semiconductor light emitting device may be directly mounted on the substrate 3002 (a so-called COB type) so as to be used. Unlike the backlight unit 3000 in FIG. 18 in which the light sources 3001 emit light toward an upper side where a liquid crystal display device is disposed, a backlight unit 4000 as another example illustrated in FIG. 19 is configured such that light sources 4001 mounted on a substrate 4002 emit light in a lateral direction, and the emitted light may be made incident to a light guide plate 4003 so as to be converted into a surface light source. Light, passing through the light guide plate 4003, is emitted upwardly, and in order to enhance light extraction efficiency, a reflective layer 4004 may be disposed on a lower surface of the light guide plate 4003.

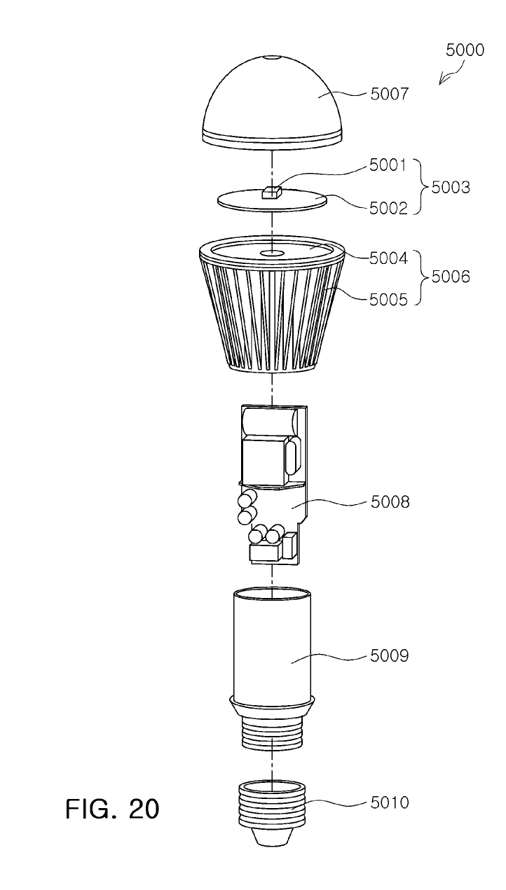

FIG. 20 is a view illustrating an example of an application of a semiconductor light emitting device to an illuminating device. Referring to the exploded perspective view of FIG. 20, an illuminating device 5000 is illustrated, for example, as a bulb-type lamp, and includes a light emitting module 5003, a driving unit 5008, and an external connection unit 5010. Also, the illuminating device 5000 may further include external structures such as external and internal housings 5006 and 5009 and a cover unit 5007. The light emitting module 5003 may have the foregoing semiconductor light emitting device 5001 and a circuit board 5002 with the light emitting device 5001 mounted thereon. In the present example, it is illustrated that a single semiconductor light emitting device 5001 is mounted on the circuit board 5002, but the present application is not limited thereto and a plurality of semiconductor light emitting devices may be mounted as necessary. Also, the semiconductor light emitting device 5001 may be fabricated in the form of a package and subsequently mounted on the circuit board 5002, rather than being directly mounted thereon.

Also, in the illuminating device 5000, the light emitting module 5003 may include the external housing 5006 serving as a heat dissipation unit, and in this case, the external housing 5006 may include a heat dissipation plate 5004 disposed to be directly in contact with the light emitting module 5003 to enhance heat dissipation effect. Also, the illuminating device 5000 may include the cover unit 5009 installed on the light emitting module 5003 and having a convex lens shape.

The driving unit 5008 is installed in the internal housing 5009 and connected to the external connection unit 5010 having a socket structure to receive power from an external power source. Also, the driving unit 5008 may serve to convert power into an appropriate current source for driving a semiconductor light emitting device 5001 of the light emitting mode 5003, and provide the same. For example, the driving unit 5008 may be configured as an AC-DC converter, a rectifying circuit component, or the like.

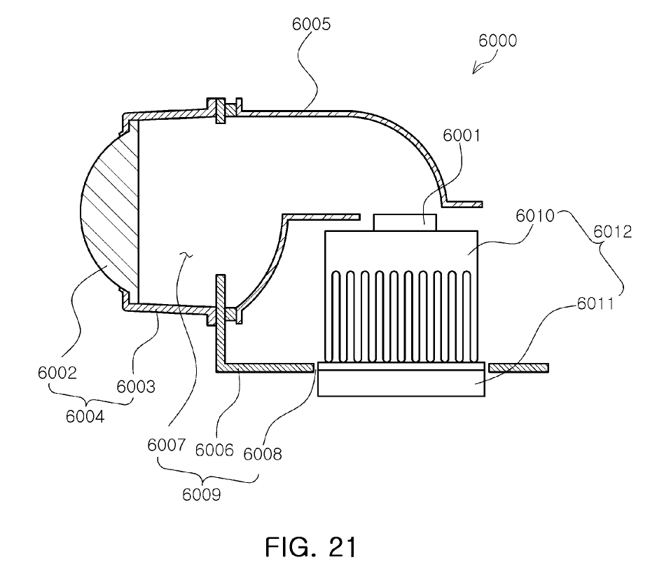

FIG. 21 is a view illustrating an example of an application of a semiconductor light emitting device to a head lamp. Referring to FIG. 21, a head lamp 6000 used as a vehicle lamp, or the like, may include a light source 6001 a reflective unit 6005, and a lens cover unit 6004. The lens cover unity 6004 may include a hollow guide 6003 and a lens 6002. Also, the head lamp 6000 may further include a heat dissipation unit 6012 dissipating heat generated by the light source 6001 outwardly. In order to effectively dissipate heat, the heat dissipation unit 6012 may include a heat sink 6010 and a cooling fan 6011. Also, the head lamp 6000 may further include a housing 6009 fixedly supporting the heat dissipation unit 6012 and the reflective unit 6005, and the housing 6009 may have a central hole 6008 formed on one surface thereof, in which the heat dissipation unit 6012 is coupled. Also, the housing 6009 may have a front hole 6007 formed on the other surface integrally connected to the one surface and bent in a right angle direction. The front hole 6007 may allow the reflective unit 6005 to be fixedly positioned above the light source 6001. Accordingly, a front side is opened by the reflective unit 6005, and the reflective unit 6005 is fixed to the housing 6009 such that the opened front side corresponds to the front hole 6007, and light reflected by the reflective unit 6005 may pass through the front hole 6007 so as to be output outwardly.

As set forth above, according to certain examples of the present application, since the electrode is formed to only cover a portion of a lateral surface of the nanostructure in an upper side of the nanostructure to reduce light absorption to the electrode, light extraction efficiency can be improved.

Also, since the lateral surface of the nanostructure in the semiconductor light emitting device having a nanostructure is sloped, light extraction efficiency can be increased.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

What is claimed is:

1. A semiconductor light emitting device comprising:
a substrate;
a plurality of nanostructures spaced apart from one another on the substrate, the plurality of nanostructures including a first conductivity-type semiconductor layer core, an active layer, and a second conductivity-type semiconductor layer;
a filler for filling spaces between the plurality of nanostructures and formed to be lower than the plurality of nanostructures; and
an electrode formed to cover upper portions of the plurality of nanostructures and portions of lateral surfaces of the plurality of nanostructures and electrically connected to the second conductivity-type semiconductor layer.

2. The semiconductor light emitting device of claim 1, wherein a height of the filler is equivalent to ⅗ or greater of a height of the plurality of nanostructures.

3. The semiconductor light emitting device of claim 1, wherein the electrode is formed to cover a portion of the lateral surface of the plurality of nanostructures, equivalent to ⅖ or less of the length of the lateral surface of the plurality of nanostructures from an upper portion of the plurality of nanostructures.

4. The semiconductor light emitting device of claim 1, wherein the filler comprises a light-transmissive material.

5. The semiconductor light emitting device of claim 1, further comprising:
a laterally sloped layer formed on a lateral surface of at least one of the plurality of nanostructures, and sloped at a predetermined angle with respect to an upper surface of the substrate.

6. The semiconductor light emitting device of claim 5, wherein the predetermined angle is greater than 45° and less than 90°.

7. The semiconductor light emitting device of claim 1, wherein the plurality of nanostructures having a nanorod shape.

8. The semiconductor light emitting device of claim 1, wherein the plurality of nanostructures include a plurality of semi-polar surfaces.

9. The semiconductor light emitting device of claim 1, wherein the electrode comprises a light-reflective material.

10. The semiconductor light emitting device of claim 1, wherein the plurality of nanostructures have the same diameter.

11. The semiconductor light emitting device of claim 1, wherein the plurality of nanostructures have different diameters.

12. The semiconductor light emitting device of claim 1, wherein the plurality of nanostructures have a pyramid or polypyramid shape.

13. A semiconductor light emitting device comprising:
a substrate;
a plurality of nanostructures having nanorod shapes, spaced apart from one another on the substrate, the plurality of nanostructures including a first conductivity-type semiconductor layer core, an active layer, and a second conductivity-type semiconductor layer; and
a laterally sloped layer formed on at least one of the plurality of nanostructures, the laterally slope layer sloped at a predetermined angle with respect to an upper surface of the substrate.

14. The semiconductor light emitting device of claim 13, wherein the predetermined angle is greater than 45° and less than 90°.

15. The semiconductor light emitting device of claim 13, wherein the plurality of nanostructures include a first conductivity-type semiconductor layer core, an active layer surrounding the core, and a second conductivity-type semiconductor layer surrounding the active layer.

16. The semiconductor light emitting device of claim 13, wherein a light emitting unit including the plurality of nanostructures and the laterally sloped layer has a trapezoidal shape when viewed from a side thereof.

17. The semiconductor light emitting device of claim 13, wherein the laterally sloped layer comprises the same material as that of the second conductivity-type semiconductor layer.

18. The semiconductor light emitting device of claim 13, wherein the laterally sloped layer comprises a material having a refractive index different from that of the second conductivity-type semiconductor layer.

19. The semiconductor light emitting device of claim 13, wherein the plurality of nanostructures have the same diameter.

20. The semiconductor light emitting device of claim 13, wherein the plurality of nanostructures have different diameters.
